(19) United States
(12) Patent Application Publication
(10) Pub. No.: US 2025/0245407 A1
(43) Pub. Date: Jul. 31, 2025

(54) METHOD FOR CREATING A MODEL FOR RECOGNITION OF THE ORIGIN OF OIL SPILLS AT SEA USING MACHINE LEARNING

(71) Applicants: PETRÓLEO BRASILEIRO S.A. – PETROBRAS, Rio de Janeiro (BR); PONTIFÍCIA UNIVERSIDADE CATÓLICA DO RIO DE JANEIRO, Rio de Janeiro (BR)

(72) Inventors: Gil Marcio AVELINO SILVA, Rio de Janeiro (BR); Moises Henrique PEREIRA, Rio de Janeiro (BR); Walter Freddy HERRERA JIMÉNEZ, Rio de Janeiro (BR); Jarbas Vicente POLEY GUZZO, Rio de Janeiro (BR); Paulo Romero ZANCONATO PINTO, Rio de Janeiro (BR); Fernando PELLON DE MIRANDA, Rio de Janeiro (BR); Italo DE OLIVEIRA MATIAS, Rio de Janeiro (BR); Wagner Leonel BASTOS, Rio de Janeiro (BR); Francisco Fábio DE ARAÚJO PONTE, Rio de Janeiro (BR); Joelson Vialle MATHIAS DA SILVA, Rio de Janeiro (BR); Sarah BARRÓN TORRES, Rio de Janeiro (BR); Tiago DE SOUZA MOTA, Rio de Janeiro (BR); Joelma PIMENTEL LOPES, Rio de Janeiro (BR); Rafael Barbosa NASSER, Rio de Janeiro (BR); Gustavo ROBICHEZ DE CARVALHO, Rio de Janeiro (BR)

(21) Appl. No.: 19/017,722

(22) Filed: Jan. 12, 2025

(30) Foreign Application Priority Data
Jan. 31, 2024 (BR) 1020240020235

(51) Int. Cl. G06F 30/28; G06F 30/27

(52) U.S. Cl. CPC G06F 30/28; G06F 30/27

(57) ABSTRACT

The present disclosure is directed to embodiments of a method that aims at improving the process of recognizing the origin of oil spills, sampled as orphan spots on the sea surface, especially due to the time spent nowadays on these activities (hours and/or days for data analysis and interpretation) and given the difficulty of obtaining such accurate/reliable results, given the subjectivity inherent to human resources. The method described herein aims at significantly contributing to the geochemical research through the use of mathematical routines and machine learning for the generation of classification models, by means of pattern recognition, serving as a decision-making instrument in exploratory biases.

### FIELD OF THE DISCLOSURE

The present disclosure consists of a method for identifying the oil complex of origin of oil samples from spills at sea by using mathematical methods of multivariate data analysis and machine learning algorithms (e.g., Linear SVM, Decision Tree, Random Forest, Gaussian Naive Bayes, among others), which lead to the development of models for automatic classification of possible spills (oily residues and orphan stains) from production areas.

### DESCRIPTION OF THE STATE OF THE ART

Geochemistry is the science that studies the distribution and migration of chemical elements in a given location on the planet. Organic geochemistry, in turn, is the branch that studies the distribution of the element carbon in animals and plants. This includes petroleum geochemistry, defined as the application of chemical principles to the study of the origin, generation, migration, accumulation and alteration of this fossil fuel.

Petroleum is a complex mixture of hundreds of thousands of components—hydrocarbons in the physical, solid, liquid and gaseous states, in addition to small amounts of oxygen, sulfur and metals, classified as saturated, aromatic and polar. Among the organic species that compose the same, there are biomarker compounds, originating from the decomposition of living beings that kept their carbon skeletons practically unchanged in the step of transformation of organic matter into petroleum.

Most comparisons of petroleum, rock-oil or oil-oil, use ratios between the geochemical biomarkers, as these tend to calculate more accurate results than the absolute concentrations, provided that the analytical conditions are identical for the sample and the suspected oils. In this context, the application of the petroleum geochemistry targets two very characteristic scenarios, exploratory and forensic.

In the first scenario, the geochemical analysis of the oil fractions helps to assess the type of source rock, thermal maturation and depositional paleoenvironment. The characteristic distribution of biomarker compounds of a petroleum is also useful to verify the possible biodegradation in its chemical composition due to secondary processes that occur after the accumulation of oil in a reservoir. The main objective of the investigation is to discover a new exploratory frontier and then determine the type, quality, origin and thermal maturation of the oil from a given sedimentary basin.

In the Brazilian marginal basins, formed during the separation of the South American and African continents, the oils generated are derived from source rocks that present diverse chemical characteristics, resulting from the physical-chemical conditions of the depositional paleoenvironments in which the organic matter was deposited. These sedimentation environments are classified as lacustrine, transitional (marine-deltaic) and marine.

In exploratory processes in these basins, considering direct and indirect investigation methods, the petroleum geochemistry becomes an important tool to aid in the discovery and assessment of oil deposits, both for the final result and for the low costs involved.

From a forensic perspective, the geochemistry acts in the characterization of oil fluids on land and at sea, supporting criminal investigations in order to identify the origin of any oil residue. It can also be applied in the verification of leak zones in reservoirs, legal support in class actions, monitoring of the Brazilian coast, assistance in monitoring beaches, among others.

There are numerous situations in which the identification of the origin of an oil spill is necessary—shipwreck or collision of oil tankers with oil storage, pollution caused by tank washing operations in vessels, operational lacks of control on oil platforms, discharge of oily water from production platforms, spills during off-load operations, leaks in pipelines or monobuoys.

The paper authored by TORRES et al. (DATA MINING IN ORGANIC GEOCHEMISTRY: CASE STUDY IN POTIGUAR BASIN. São Paulo, UNESP, Geociencias, v. 41, n. 1, p. 105-114, 2022) addresses to the classification of oil samples and uses data mining and machine learning techniques in the organic geochemistry, with a specific study of oils from the Potiguar Basin, aiming at predicting the origin of the depositional environment (Marine, Lacustrine or Siliciclastic). In addition, this document does not address to samples from oil spills. Samples from oil spills or their derivatives at the sea are subjected to weathering processes, such as: loss of light fractions, oxygenation of fractions, biodegradation, sedimentation, and others.

CHEN's Master Thesis document (MACHINE LEARNING BASED APPROACHES FOR CLASSIFICATION OF OIL SPILLS AND MICROPLASTICS IN MARINE ENVIRONMENTS. May, 2021, 150 p.) describes a method that uses the Random Forest algorithm for oil classification, focusing on the entry and processing of biomarkers with a focus on environmental pollution. Said Master Thesis presents machine learning-based approaches for the classification of oil spills and microplastics in marine environments. This is relevant for environmental modeling in environmental engineering and management, providing a deeper understanding of the environmental problems and facilitating decision-making processes. Unlike Chen's Thesis, the present disclosure focuses on identifying the source of the oil spill, be it an oil complex or a specific production unit. In addition, the proposed disclosure uses a wider range of geochemical biomarkers, 72 in total, including all biomarkers in the data entry of the method. These biomarkers undergo a filtering phase to preserve only the most relevant ones for classification, which results in greater precision. Additionally, the developed application provides a ranking of the most likely sources, together with the respective probability of belonging to each of the same.

The document SOSNOWSKI et al. (MACHINE LEARNING TECHNIQUES FOR CHEMICAL AND TYPE ANALYSIS OF OCEAN OIL SAMPLES VIA HANDHELD SPECTROPHOTOMETER. Biosensors and Bioelectronics: X device 10: 100128, 2002) describes a method and a mobile device for identifying samples of oil spills, using a trained machine learning model. This model classifies the oil types, such as marine gas oil (MGO) or Bunker A (BA). In addition, the paper details the development of a portable fluorescence spectrometry device designed to identify samples from oil spills at the ocean. To classify the oil type and analyze the SARA (saturates, aromatics, resins, and asphaltenes) contents in the samples, this document employs machine learning techniques, including the Support Vector Machine (SVM) algorithm. In contrast, the present disclosure goes much further by providing detailed information about the specific origin of the oil, including oil complexes. This represents a significantly different value compared to the classification of oil types (saturates, aromatics, NSO) described in this document.

Document CN116070148A describes a method and system for classifying oil sources based on a Deep Neural Network model. This model uses geochemical biomarkers for potential hydrocarbon source rock extraction and sandstone extraction. The present disclosure and document CN116070148A share similar objectives, both related to the oil industry and involving methods for classifying and identifying oil samples. However, there are notable differences in the methodology and specific techniques employed in each of them. Document CN116070148A makes use of a Deep Neural Network model to classify oil sources based on biomarkers, with a focus on the geological oil exploration. On the other hand, the present disclosure focuses on the identification of oil systems from geochemical biomarkers of samples of oils spilled at sea. The present disclosure employs mathematical routines for multivariate data analysis and several machine learning algorithms to develop models for recognizing compositional patterns in oil spills. It is important to note that CN116070148A does not mention the family of oils.

In view of this, no document of the state of the art discloses a well-defined methodology for analyzing and quickly determining the origin of oily residues such as that of the present disclosure, which presents the necessary precision even in production areas with great compositional similarity.

In this way, the present disclosure is achieved through the steps of: a) adopting a numerical compositional approach and supervised classification of oils, using multivariate statistics to analyze redundant variables and reduce dimensionality; and b) applying Machine Learning to build models to infer the oil complex by testing several algorithms.

The importance of the user identifying the oil complex from spill samples was what guided the development of the present disclosure, which aims at improving the use of mathematical and statistical tools in Geochemistry. The process described herein aims at significantly contributing to exploratory and forensic oil research.

The referenced disclosure presents advantages since it now allows greater reliability—given the use of artificial intelligence, which reduces the subjectivity of human resources to obtain results—and speed—activities that used to take hours and/or days can be carried out in minutes—in the diagnosis of the origin of oils from important production areas.

### BRIEF DESCRIPTION OF THE DISCLOSURE

The present disclosure is directed to embodiments of methods for creating a model for recognizing the origin of oil spills at sea by using mathematical methods and Machine Learning to generate classification models, with which it is possible to predict, with at least 80% of hits, the oil field or the source of samples from the exploratory or forensic oil geochemistry investigations.

An embodiment of a method aims at making a significant contribution to geochemical research, serving as an instrument for identifying orphaned oil spills at sea, which may, for example, be associated with reservoirs with natural oil spills to the surface (exudation), as well as illegal oil spills from vessels, among others.

The input data set comprised data from 2,200 oil samples from spills with 75 predictive attributes, derived from 72 geochemical biomarkers, in addition to 3 categorical parameters, for the construction of the classification model. In a second step, 3 oil samples also from spills that were not part of the initial data set were used for the application/validation of the proposed model. There are 45 possible fields for matching when applying machine learning to build the classification model.

The initial step of the disclosure is data pre-processing, which includes (i) identifying inconsistencies in the data, missing values (null values) and outliers, (ii) selecting the attributes, and (iii) normalizing the variables.

Subsequently, an exploratory analysis and attribute selection step was carried out, which comprises: (i) using univariate and multivariate methods to understand the statistical properties of the data by means of a histogram, (ii) verifying the similarity of the attributes and reducing the dimensionality of the data by means of a correlation matrix, multidimensional scaling (MDS) and principal component analysis, (iii) forming clusters using K-Means clustering, and (iv) selecting a subset of attributes by means of a distance matrix.

In the subsequent step of applying machine learning, 7 algorithms were tested to identify those that best respond to pattern recognition associated with identifying the origin of the oil. For each algorithm, a model was proposed along with its respective optimized parameters and best attributes for identifying the origin of the oil.

The models, generated from training the algorithms with a percentage of the input data by means of the pattern recognition, return expected responses (corresponding oil field) for each set of characteristics of the tested samples. In this way, the prediction for each oil spill sample depends on the similarity of its attributes with those available in the other samples in the database.

The last step corresponds to the application and validation of the model that presents the best classification performance in “new” samples for prediction.

The exposed disclosure is used in the modeling of classifiers that speed up the process of recognizing the origin of oils. In addition to saving time—computer processing takes just a few minutes, unlike manual work that takes hours and/or days, there is also the reliability in the method, given the use of the artificial intelligence, eliminating the great dependence on human resources and their subjectivity to obtain the results.

### BRIEF DESCRIPTION OF THE DRAWINGS

The present disclosure will be described in more detail below, with reference to the attached figures that, in a schematic manner and not limiting the inventive scope, represent:

FIG. 1: Steps used in the development of the classification model, according to embodiments of the present disclosure;

FIG. 2: Initial and final interpretations of the classification of fluids from well X after the data processing and elimination of outliers phase, with identification of a deep accumulation that escaped the initial geochemical assessment, according to embodiments of the present disclosure(

FIG. 3: Correlation matrix, according to an embodiment of the present disclosure;

FIG. 4: Multidimensional Scaling, according to embodiments of hr present disclosure;

FIG. 5: Normalization (frequency histograms of the variable, accumulated frequency and distribution after transformation), accounting to embodiments of the present disclosure;

FIG. 6: Importance of each attribute for the Decision Tree (DT) in the characterization of the samples for pattern recognition, according to embodiments of the present disclosure;

FIG. 7: Confusion matrix resulting from the DT method, according to embodiments of the present disclosure;

FIG. 8: Comparative graph of the accuracies of the ML classifiers, according to embodiments of the present disclosure; and

FIG. 9: Test application of the numerical model obtained in three “new” samples, according to embodiments of the present disclosure.

### DETAILED DESCRIPTION OF THE DISCLOSURE

The disclosure relates to a series of mathematical methods, including normalization and identification of outliers (anomalous data), removal of null data, duplicate data, selection and removal of attributes (e.g., redundant parameters), in addition to the application of statistical methods to better understand the data set and subsequent construction of classification models by using machine learning.

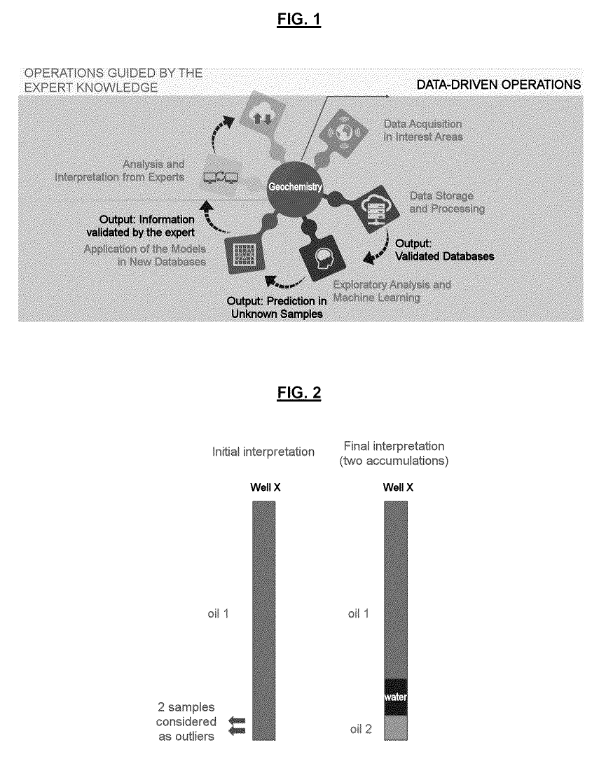

FIG. 1 illustrates the methodology applied in the present disclosure with regard to data-driven operations (gray portion). The operations guided by the expert's knowledge (green portion) refer to the application of the results acquired by using the method proposed herein.

### 1. Input Data

2,200 oil samples from spills with 75 predictive attributes, derived from 72 geochemical biomarkers, in addition to 3 categorical parameters, were used to build the classification model. In a second step, 3 oil samples also from spills that were not part of the initial data set were used to apply/validate the proposed model.

The samples were analyzed in the geochemistry laboratory to determine saturated biomarkers. The parameters obtained are information about the organic matter, the paleoenvironment of origin and the level of thermal maturation reached by the generation of rocks during their deposition. The systems for identifying the source of an oil spill are mainly based on the determination of oil biomarkers, particularly terpanes and steranes. Table 1 presents the families of monitored compounds with their respective characteristic ions.

TABLE 1
Families of monitored ions for the saturated fraction.

| Monitored | |
|---|---|
| Ion (m/z) | Family of Monitored Compounds |
| 57 | Normal and branched alkanes |
| 177 | 25-norhopanes |
| 191 | Terpanes, Gammacerane, Oleanane, homohopanes |
| 205 | Methylhopanes |
| 217 | Steranes |
| 218 | ββ steranes |
| 231 | Triaromatic steroids |
| 259 | Diasteranes |

Table 2 presents some of the fractions of the ions m/z 177, 191, 217, 218 and 259 selected for monitoring. These fractions are commonly used in oil spill studies and in organic geochemistry.

TABLE 2
Some of the compounds monitored in the saturated fraction.

| | | Abbreviated | |
|---|---|---|---|
| No. | Compound Name | Name m/z | Ion |
| 1 | 17α(H)21β(H)-25-norhopane | 25Nor | 177 |
| 2 | C19 tricyclic terpane | TR19 | 191 |
| 3 | C20 tricyclic terpane | TR20 | 191 |
| 4 | C21 tricyclic terpane | TR21 | 191 |
| 5 | C22 tricyclic terpane | TR22 | 191 |
| 6 | C23 tricyclic terpane | TR23 | 191 |
| 7 | C24 tricyclic terpane | TR24 | 191 |
| 8 | C25 tricyclic terpane (S) | TR25A | 191 |
| 9 | C25 tricyclic terpane (R) | TR25B | 191 |
| 10 | C24 tetracyclic terpane (TET) | TET24 | 191 |
| 11 | C26 tricyclic terpane (S) | TR26A | 191 |
| 12 | C26 tricyclic terpane (R) | TR26B | 191 |
| 13 | C28 tricyclic terpane (S) | TR28A | 191 |
| 14 | C28 tricyclic terpane (R) | TR28B | 191 |
| 15 | C29 tricyclic terpane (S) | TR29A | 191 |
| 16 | C29 tricyclic terpane (R) | TR29B | 191 |
| 17 | 18α(H)-22,29,30-trisnorneohopane | TS | 191 |
| 18 | 17α(H)-22,29,30-trisnorhopane | TM | 191 |
| 19 | C30 tricyclic terpane (S) | TR30A | 191 |
| 20 | C30 tricyclic terpane (R) | TR30B | 191 |
| 21 | 17α(H)21β(H)-28,30-bisnorhopane | H28 | 191 |
| 22 | 17α(H)21β(H)-25-norhopane | NOR25H | 191 |
| 23 | 17α(H)21β(H)-30-norhopane (C29 Tm) | H29 | 191 |
| 24 | 18α(H)-30-norneohopane (C29 Ts) | C29TS | 191 |
| 25 | 15α(Methyl)17α(H)-27-norhopane | DH30 | 191 |
| | (C30 diahopane) | | |
| 26 | 17β(H)21α(H)-30-norhopane | M29 | 191 |
| | (normorethane) | | |
| 27 | 17α(H)-21β(H)-hopane | H30 | 191 |
| 28 | 17β(H)21α(H)-hopane (morethane) | M30 | 191 |
| 29 | 17α(H)21β(H) 22S-homopane | H31S | 191 |
| 30 | 17α(H)21β(H) 22R-homopane | H31R | 191 |
| 31 | Gammacerane | GAM | 191 |
| 32 | 17α(H)21β(H) 22S-bishomopane | H32S | 191 |
| 33 | 17α(H)21β(H) 22R-bishomopane | H32R | 191 |
| 34 | 17α(H)21β(H) 22S-trishomopane | H33S | 191 |
| 35 | 17α(H)21β(H) 22R-trishomopane | H33R | 191 |
| 36 | 17α(H)21β(H) 22S-tetrahomopane | H34S | 191 |
| 37 | 17α(H)21β(H) 22R-tetrahomopane | H34R | 191 |
| 38 | 17α(H)21β(H) 22S-pentahomopane | H35S | 191 |
| 39 | 17α(H)21β(H) 22R-pentahomopane | H35R | 191 |
| 40 | C21 sterane | S21 | 217 |
| 41 | C22 sterane | S22 | 217 |
| 42 | 13β(H)17α(H) 20S-cholestane | DIA27S | 217 |
| | (diasterane) | | |
| 43 | 13β(H)17α(H) 20R-cholestane | DIA27R | 217 |
| | (diasterane) | | |
| 44 | 5α(H)14α(H)17α(H) 20S-cholestane | C27S | 217 |
| 45 | 5α(H)14α(H)17α(H) 20R-cholestane | C27R | 217 |
| 46 | 24-Ethyl-5α(H)14α(H)17α(H) 20S- | C29S | 217 |
| | cholestane | | |
| 47 | 24-Ethyl-5α(H)14β(H)17β(H) 20R- | C29BBR | 217 |
| | cholestane (+5βαα) | | |
| 48 | 24-Ethyl-5α(H)14β(H)17β(H) 20S- | C29BBS | 217 |
| | cholestane | | |
| 49 | 24-Ethyl-5α(H)14α(H)17α(H) 20S- | C29R | 217 |
| | cholestane | | |
| 50 | 24-Methyl-5α(H)14β(H)17β(H) 20S- | C28ABBS | 218 |
| | cholestane | | |
| 51 | 24-Methyl-5α(H)14β(H)176(H) 20R- | C28ABBR | 218 |
| | cholestane | | |
| 52 | C30-21R Tetracyclic Polypropenoid | C30TP1 | 259 |
| 53 | C30-21S Tetracyclic Polypropenoid | C30TP2 | 259 |

The diagnostic ratios of the saturated biomarkers that include the 72 attributes used in the disclosure (Table 3) are calculated from the ion fractions. The application in oil characterization studies is used to correlate oil and source rock, determine the type of depositional paleoenvironment, evaluate thermal maturation and infer the level of oil biodegradation in the reservoir. In addition to those listed in Table 3, the 3 categorical attributes of the database are: ‘Sample’, ‘Well’, ‘Field’.

TABLE 3
List of attributes and used diagnostic reasons, with details of the calculations.

| No | Attribute Name | Ratios between Biomarkers |
|---|---|---|
| 1 | ′19_23TRI′ | 19/23TRI = TR19/TR23 |
| 2 | ′21_23TRI′ | 21/23TRI = TR21/TR23 |
| 3 | ′21 + 22_STER′ | 21 + 22/STER = (S21 + S22)/Total Steranes Concentration |
| 4 | ′23_24TRI′ | 23/24TRI = TR23/TR24 |
| 5 | ′24_25TRI′ | 24/25TRI = TR24/TR25 |
| 6 | ′25NOR_Hopane′ | 25NOR/HOPANE = 25NOR/Hopane (Ion 177) |
| 7 | ′25NOR_25NOR + | 25NOR/(25NOR + H29) = 25NOR/(25NOR + H29) |
| | C29HOP′ | |
| 8 | ′26_25TRI′ | 26/25TRI = TR26/TR25 |
| 9 | ′26_28TRI′ | 26/28TRI = TR26/TR28 |
| 10 | ′27_29BBRS218′ | 27/29 ββRS (218) = C27αββRS/C29αββRS |
| 11 | ′27_29BBS218′ | 27/29 ββS (218) = C27αββS/C29αββS |
| 12 | ′28_29BBS218′ | 28/29 ββS (218) = C28αββS/C29αββS |
| 13 | ′28_29BBRS218′ | 28/29 ββRS (218) = C28αββRS/C29αββRS |
| 14 | ′29_30H′ | 29/30H = (H29 + C29Ts)/H30 |
| 15 | ′BNH_BNH + 25NOR′ | BNH/(BNH + 25NOR) = BNH/(BNH + 25NOR) |
| 16 | ′BNH_BNH + | BHN/(BNH + H29) = BNH/(BNH + H29) |
| | C29HOP′ | |
| 17 | ′C29BB_C29′ | C29ββ/C29 = (C29ββR + C29ββS)/(C29R + C29S) |
| 18 | ′C29BB_C29AA′ | 29/29 ββαα = (C29ββR + C29ββS)/(C29ααR + C29ααS) |
| 19 | ′C29BBR_C29R′ | 29/29 ββR = C29ββR/C29R |
| 20 | ′C29BBS_C29R′ | 29/29 ββSR (218) = C29ββS/C29R |
| 21 | ′DIA_C27AA′ | DIA/C27αα = (DIA27S + DIA27R)/(C27S + C27R) |
| 22 | ′DIA30_C27AA′ | DIA30/C27αα = (C30TP1 + C30TP2)/(C27S + C27R) |
| 23 | ′DIAH_H30′ | DIAH/H30 = DH30/H30 |
| 24 | ′DITERP_H30′ | DITERP/H30 = TR21 + TR22 + TR23 + TR24 + TR25A + |
| | | TR25B + TR26A + TR26B + TR28A + TR28B + TR29A + TR29B)/H30 |
| 25 | ′GAM_H30′ | GAM/H30 = Gammacerane/H30 |
| 26 | ′GAM_TR23′ | GAM/TR23 = Gammacerane/TR23 |
| 27 | ′H_HM2930′ | H30/M2930 = H30/(M29 + M30) |
| 28 | ′H28_H29′ | H28/H29 = H28/H29 |
| 29 | ′H28_TR23′ | H28/TR23 = H28/TR23 |
| 30 | ′H29_C29TS′ | H29/C29Ts = H29/C29TS |
| 31 | ′H29_H30′ | H29/H30 = H29/H30 |
| 32 | ′H3035_ST′ | HOP/STER = Total concentration of hopanes/Total |
| | | concentration of steranes |
| 33 | ′H30_C27AA′ | H30/C27αα = H30/(C27S + C27R) |
| 34 | ′H31S_H31′ | H31S/H31 = (H31S)/(H31S + H31R) |
| 35 | ′H32S_H32′ | H32S/H32 = (H32S)/(H32S + H32R) |
| 36 | ′H33S_H33′ | H33S/H33 = (H33S)/(H33S + H33R) |
| 37 | ′H35_H34′ | H35/H34 = (H35S + H35R)/(H34S + H34R) |
| 38 | ′HOP_STER′ | HOP/STER = Total concentration of hopanes/Total |
| | | concentration of steranes |
| 39 | ′NORC29Ts_{—} | H29/(H29 + NORNEO) = H29/(H29 + C29TS) |
| | NORC29Ts + TsC29′ | |
| 40 | ′P27AAAR′ | % 27αααR (218) = 100*(C27αααR)/(C27αααR + C28αααR + |
| | | C29αααR) |
| 41 | ′P27aBBReS218′ | % 27ββRS (218) = 100*(C27αββRS)/(C27αββRS + |
| | | C28αββRS + C29αββRS) |
| 42 | ′P27BBS218′ | % 27ββS (218) = 100*(C27αββS)/(C27αββS + C28αββS + |
| | | C29αββS) |
| 43 | ′P27ST′ | % 27St = 100*(C27)/(C27 + C28 + C29) St |
| 44 | ′P28AAAR′ | % 28ααR (218) = 100*(C28αααR)/(C27αααR + C28αααR + |
| | | C29αααR) |
| 45 | ′P28aBBReS218′ | % 28ββRS (218)100*(C28αββRS)/(C27αββRS + |
| | | C28αββRS + C29αββRS) |
| 46 | ′P28BBS218′ | % 28ββS (218) = 100*(C28αββS)/(C27αββS + C28αββS + |
| | | C29αββS) |
| 47 | ′P28ST′ | % 28St = 100*(C28)/(C27 + C28 + C29) St |
| 48 | ′P29AAAR′ | % 29ααR (218) = 100*(C29αααR)/(C27αααR + C28αααR + |
| | | C29αααR) |
| 49 | ′P29aBBReS218′ | % 29ββRS (218) = 100*(C29αββRS)/(C27αββRS + |
| | | C28αββRS + C29αββRS) |
| 50 | ′P29BBS218′ | % 29ββS (218) = 100*(C29αββS)/(C27αββS + C28αββS + |
| | | C29αββS) |
| 51 | ′P29ST′ | % 29St = 100*(C29)/(C27 + C28 + C29) St |
| 52 | ′PH31′ | % H31 = 100*(H31S + H31R)/(H31S + H31R + H32S + H32R + |
| | | H33S + H33R + H34S + H34R + H35S + H35R) |
| 53 | ′PH32′ | % H32 = 100*(H32S + H32R)/(H31S + H31R + H32S + |
| | | H32R + H33S + H33R + H34S + H34R + H35S + H35R) |
| 54 | ′PH33′ | % H33 = 100*(H33S + H33R)/(H31S + H31R + H32S + H32R + |
| | | H33S + H33R + H34S + H34R + H35S + H35R) |
| 55 | ′PH34′ | % H34 = 100*(H34S + H34R)/(H31S + H31R + H32S + H32R + |
| | | H33S + H33R + H34S + H34R + H35S + H35R) |
| 56 | ′PH35′ | % H35 = 100*(H35S + H35R)/(H31S + H31R + H32S + H32R + |
| | | H33S + H33R + H34S + H34R + H35S + H35R) |
| 57 | ′NOR25H_H29′ | NOR25H/H29 = NOR25H/H29 |
| 58 | ′NOR25H_H30′ | NOR25H/H30 = NOR25H/H29 |
| 59 | ′NORNEO_H29′ | NORNEO/H29 = C29TS/H29 |
| 60 | ′S_R′ | 20S/20R St = C29S/C29R steranes |
| 61 | ′S_S + R′ | 20S/(20S + 20R) St = C29S/(C29S + C29R) steranes |
| 62 | ′STER_HOP′ | STER/HOP = Total concentration of steranes/Total |
| | | concentration of hopanes |
| 63 | ′TET24_H30′ | TET24/H30 = TET24/H30 |
| 64 | ′TET24_26TRI′ | TET24/26TRI = TET24/(TR26A + TR26B) |
| 65 | ′TNH_TNH + 25NOR′ | TNH/TNH + 25NOR = TNH/(TNH + 25NOR) |
| 66 | ′TPP′ | TPP = Tetracyclic Polyprenoid Terpanes/C27 Diasteranes |
| 67 | ′TR23_H30′ | TR23/H30 = TR23/H30 |
| 68 | ′TRIC_HOP′ | TRI/HOP = (TR19 + TR20 + TR21 + TR22 + TR23 + TR24 + TR25A + |
| | | TR25B + TR26A + TR26B + TR28A + TR28B + TR29A + TR29B + |
| | | TR30A + TR30B)/Total concentration of hopanes |
| 69 | ′TRIC_STER′ | TRI/STER = (TR19 + TR20 + TR21 + TR22 + TR23 + TR24 + |
| | | TR25A + TR25B + TR26A + TR26B + TR28A + TR28B + TR29A + TR29B + |
| | | TR30A + TR30B)/Total concentration of steranes |
| 70 | ′TRITERP_ST′ | TRI/STER = (TR19 + TR20 + TR21 + TR22 + TR23 + TR24 + |
| | | TR25A + TR25B + TR26A + TR26B + TR28A + TR28B + TR29A + TR29B + |
| | | TR30A + TR30B)/Total concentration of steranes |
| 71 | ′TS_TM′ | Ts/Tm = Ts/Tm |
| 72 | ′TS_TS + TM′ | Ts/(Ts + Tm) = Ts/Ts + Tm |

The samples and wells mentioned in this document were mischaracterized and belong to different oil fields, whose codes presented begin with the letter C and followed by a sequential number containing 3 digits (e.g., C004).

There are 45 possible fields for matching oil samples when applying machine learning to build the classification model: ‘C051’, ‘C045’, ‘C044’, ‘C008’, ‘C050’, ‘C014’, ‘C001’, ‘C041’, ‘C040’, ‘C006’, ‘C042’, ‘C048’, ‘C049’, ‘C016’, ‘C004’, ‘C033’, ‘C037’, ‘C035’, ‘C047’, ‘COil’, ‘C018’, ‘C017’, ‘C046’, ‘C021’, ‘C032’, ‘C007’, ‘C020’, ‘C005’, ‘C027’, ‘C003’, ‘C052’, ‘C036’, ‘C025’, ‘C026’, ‘C023’, ‘C015’, ‘C034’, ‘C039’, ‘C024’, ‘C031’, ‘C010’, ‘C029’, ‘C028’, ‘C022’, ‘C043’.

### 2. Data Processing, Elimination of Outliers

The initial data processing phase allowed for the cleaning and optimization of the data table, with the discovery of classification errors, sample identification errors, recognition of duplicate records, naming errors and elimination of outliers.

Outliers refer to atypical data, which differ significantly from other observations; they are anomalous compositional data, generally related to the contamination by drilling fluids, the presence of indigenous bitumens and even sample exchanges. The use of isolation forest, a Machine Learning algorithm that detects anomalies, helps remove these variables to clean the database.

A pair of oil samples with anomalous compositions were identified as outliers compared to the proposed supervised classification. The review and reinsertion of these compositions into the dataset disclosed an independent accumulation in well X (name mischaracterization to preserve confidentiality) of field C004, corresponding to the presence of a deep deposit originating from a secondary oil system and recognized in the basin to which the samples belong.

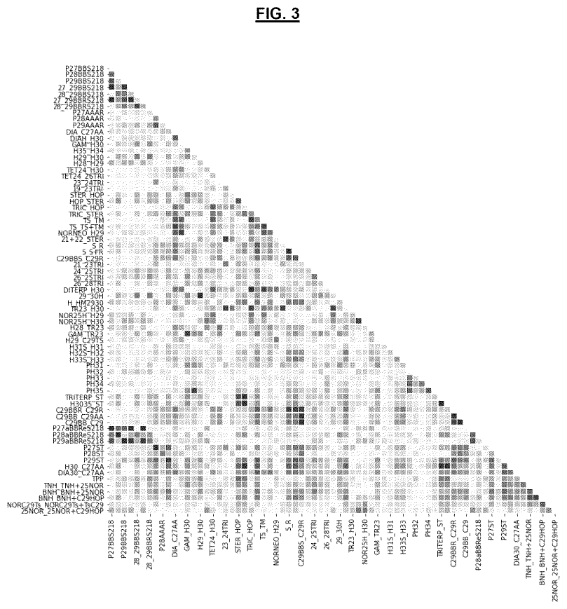

FIG. 2 illustrates, on the left, what well X was believed to be like (in the initial interpretation, this was composed of 1 accumulation of oil and the 2 samples compositionally distinct from the others were outliers); and, on the right, what the final interpretation of well X looked like (2 oil accumulations).

Next, the pre-processing was carried out in a computational way. Missing values are rows and columns with missing values, making it necessary to choose to remove or replace (for example, with the class median) the data. When checking the existence of these missing values, a column was detected, ‘25NOR_Hopane’, and it was decided to replace the empty spaces with the median. 25 lines were classified as outliers, and it was decided to eliminate the same from the data set.

Inconsistent data corresponds to duplicate or redundant data, making it necessary to delete the values. Regarding duplicates, 38 samples were observed, which were also excluded from the data.

Still at this step, the data was normalized in order to avoid scale imbalances, redundancies, among others. It is a process of organizing information that is important to guarantee the integrity of the results, which transforms the variables into the same order of magnitude, placing them in a previously defined interval.

In the end, of the initial 2200 oils, 2137 remained, with the same 74 attributes.

### 3. Exploratory Analysis and Attribute Selection

The EDA, that is, Exploratory Data Analysis, is extremely important in the modeling process. In addition to the possibility of greater understanding of the data set, the dimensionality reduction is widely intended with regard to the use of statistical techniques.

At this step, univariate and multivariate methods are used to understand the statistical properties of the data, which make it possible to highlight the presence of attributes that are not very explanatory and/or redundant, through the use of histogram, correlation matrix, multidimensional scaling, linear discriminant analysis, principal component analyses and K-Means clustering.

The histogram demonstrates the distribution of data frequencies divided into classes. It is a scatter chart, in bars or columns, used for the purpose of organizing, illustrating and facilitating the visualization of the set of variables.

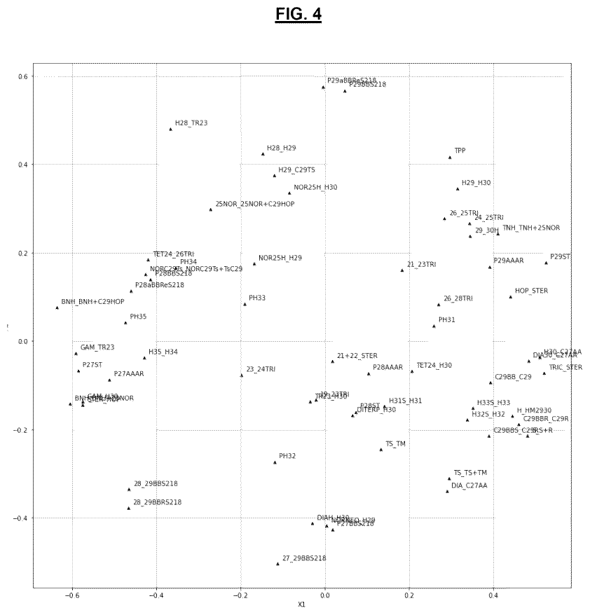

The correlation matrix displays the correlation between data as a matrix, where the color of the cell, which represents the intersection of two variables, indicates the degree of similarity between the measurements. It highlights the presence of high correlation coefficients (r), allowing the elimination of redundancies. By sing the correlation matrix, 9 variables were found to have similarity greater than 95.45% (FIG. 3). 7 columns were then removed: ‘27_29BBRS218’, ‘P27aBBReS218’, ‘TRIC_HOP’, ‘S_R’, ‘C29BB_C29AA’, ‘H3035_ST’, ‘TRITERP_ST’.

The multidimensional scaling (MDS) measures the degree of similarity or dissimilarity in multivariate structures. The correlation between the variables is used as the basis for calculating the distance matrix; the greater the distance, the greater the dissimilarity, so that the grouped variables are highly correlated, presenting high similarity and smaller distances between the same.

The MDS allowed viewing the closest/grouped attributes, in two (FIG. 4) and three dimensions. A distance less than or equal to 0.05 on the map was configured as the limit to characterize strong similarity; and the pairs TS_TS+TM and DIA_C27AA (0.030) and NORNEO_H29 and DIAH_H30 (0.037) were located. The TS_TS+TM and DIAH_H30 parameters have been removed.

The Linear Discriminant Analysis (LDA) reduces the dimensionality of data, removing redundant and dependent characteristics, and assists in classification, visualization and modeling. What is expected with the application of an LDA is that the variance between classes is maximized in relation to the intra class variance.

The Principal Component Analysis (PCA) seeks to transform the multivariate distribution into ‘principal components’ (PC), which are variables orthogonal to each other in a reduced dimensionality system. These PCs are uncorrelated (r=0) and disclose the relative contribution of each transformed variable in the multivariate system. It is a linear spectral decomposition technique that is particularly attractive in situations with a large number of variables to be considered.

The K-Means clustering separates data into clusters; it is a cluster optimization technique. The center of each cluster (centroid) is the arithmetic mean of all points belonging to the same. The number of clusters K is defined in advance and, then, each data is assigned to the centroid closest to the same, beginning the iterations, which end when the variables no longer change their cluster centers. The centroids move their positions until the convergence criteria have been met.

Of the 74 columns, 65 were kept. For the subsequent classification step, the 3 categorical parameters were also dispensed with: ‘Sample’, ‘Well’ and ‘Field’.

In the 2137 oil spill samples, 62 attributes were therefore selected—this is the optimal subset. They are: ‘P27BBS218’, ‘P28BBS218’, ‘P29BBS218’, ‘27_29BBS218’, ‘28_29BBS218’, ‘28_29BBRS218’, ‘P27AAAR’, ‘P28AAAR’, ‘P29AAAR’, ‘DIA_C27AA’, ‘GAM H30’, ‘H35_H34’, ‘H29_H30’, ‘H28_H29’, ‘TET24_H30’, ‘TET24_26TRI’, ‘23_24TRI’, ‘19_23TRI’, ‘STER_HOP’, ‘HOP_STER’, ‘TRIC_STER’, ‘TS_TM’, ‘NORNEO_H29’, ‘21+22_STER’, ‘S S+R’, ‘C29BBS_C29R’, ‘21_23TRI’, ‘24_25TRI’, ‘26_25TRI’, ‘26_28TRI’, ‘DITERP H30’, ‘29_30H’, ‘H_HM2930’, ‘TR23_H30’, ‘NOR25H_H29’, ‘NOR25H_H30’, ‘H28_TR23’, ‘GAM TR23’, ‘H29_C29TS’, ‘H31S_H31’, ‘H32S_H32’, ‘H33S_H33’, ‘PH31’, ‘PH32’, ‘PH33’, ‘PH34’, ‘PH35’, ‘C29BBR_C29R’, ‘C29BB_C29’, ‘P28aBBReS218’, ‘P29aBBReS218’, ‘P27ST’, ‘P28ST’, ‘P29ST’, ‘H30_C27AA’, ‘DIA30_C27AA’, ‘TPP’, ‘TNH_TNH+25NOR’, ‘BNH_BNH+25NOR’, ‘BNH_BNH+C29HOP’, ‘NORC29Ts_NORC29Ts+TsC29’, ‘25NOR_25NOR+C29HOP’.

### 4. Machine Learning Application

With the pre-processed database, machine learning was used to create classification models capable of predicting the field of origin of the sampled oils, based on the provided parameters.

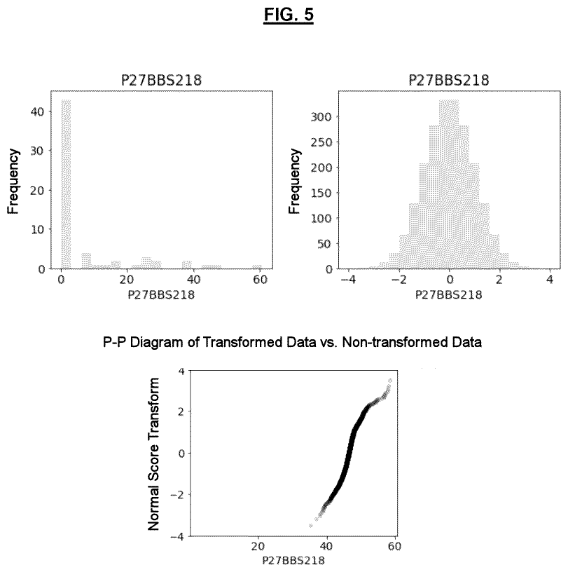

Before the actual modeling, it is important to normalize the data in order to avoid mismatches in scale, measurement units, etc.; the normal score function (mean 0 and deviation 1) was adopted for this purpose. In FIG. 5, the attribute ‘P27BBS218’ exemplifies the importance of normalizing the data set; on the left, there is the histogram of the original data and, on the right, of the transformed data. As can be seen, before the normalization, the data set contained an isolated frequency peak that could later indicate inconsistency in the data or lead to interpretation errors on the part of the algorithm. Below, the p-p diagram of the original data vs. transformed data demonstrates how the data set adjusted well to the transformation by the normal score function.

Once this was done, seven methods were tested, which have good applicability and are frequently used in the literature for geochemical investigations, namely, Decision Tree (DT), Random Forest (RF), Gaussian Naive Bayes (GNB), K-Nearest Neighbors (KNN), Artificial Neural Networks (ANN), Support Vector Machine (SVM) and Linear Discriminant Analysis (LDA). The ratio of 80% of the samples for training (1709) and 20% for testing (428) was assumed.

The models, trained with a percentage of the input data through pattern recognition, return the expected responses (corresponding oil field) for each set of characteristics of the samples tested. In this way, the prediction for each oil spill sample is dependent on the similarity of its attributes with those available from the other samples in the database.

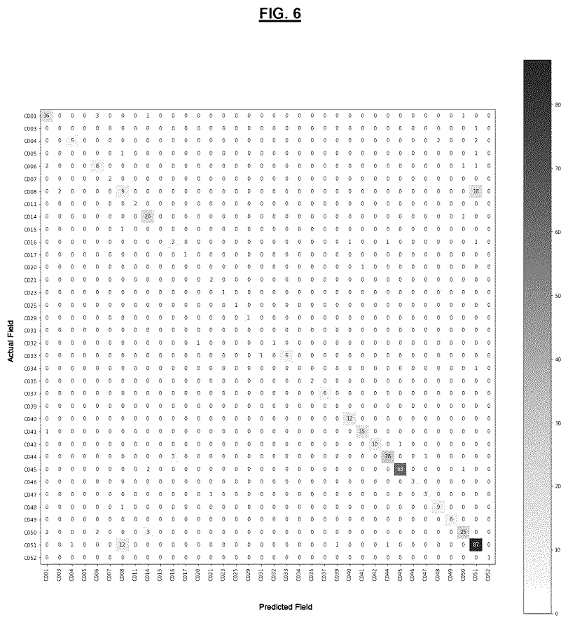

The resulting confusion matrices for each of the ML algorithms reflect the number of correct classifications by the predicted classifications for each class. These tables (e.g., FIG. 6) allow visualizing the performance of the algorithms, where each row represents the instance of the predicted class and each column provides the current class. The division of the sum of the main diagonal (correct predictions) by the total number of samples is the accuracy, which shows whether the model is adequate or whether it needs to be improved.

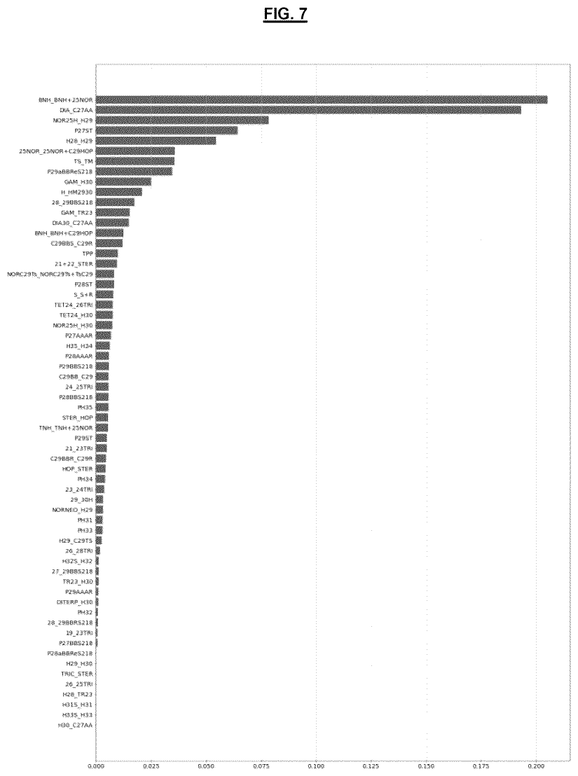

The DT model achieved an accuracy of 82%, that is, of all the samples tested, this was the percentage of hits; in this case, the accumulated variance in 10-15 attributes was already quite significant, with all the rest being of little relevance in characterizing the samples for the pattern recognition (FIG. 7).

The RF model achieved 91% of overall accuracy, which means that, of all the samples tested, this was the percentage of hits. Unlike DT, this time, a more balanced distribution of the variance is observed among the 62 parameters.

The accuracy of the GNB model reached 84%, whereas that of KNN was 86%. For the ANN model, it was 88%, while that of SVM reached 79%. The last model studied, LDA, reached 87% of accuracy, that is, of all the samples tested, this was the percentage of hits.

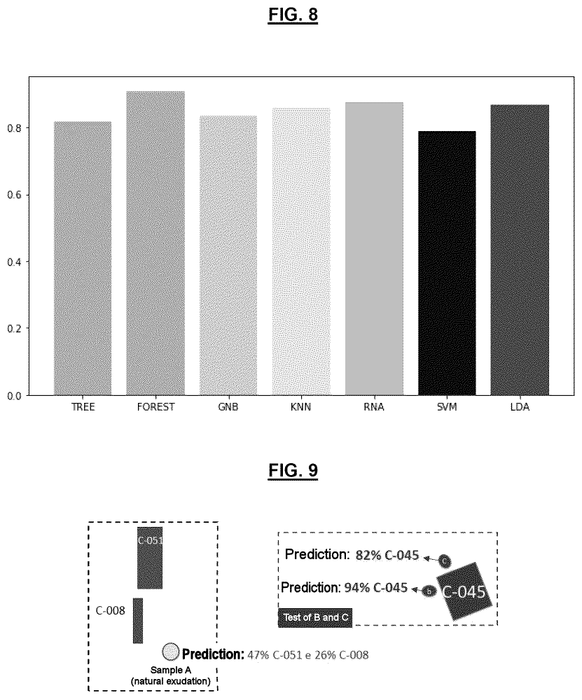

Seven classification models were obtained, one for the best combination of parameters of each ML algorithm tested, combined with the best predictive attributes. Among them, the one that returned the highest accuracy, 91%, was RF, followed by ANN, LDA, KNN, GNB and DT. The algorithm that presented the worst performance was SVM, with 79% (Table 4 and FIG. 8).

TABLE 4
Overall accuracies of the different ML methods.

| Method | DT | RF | GNB | KNN | ANN | SVM | LDA |
|---|---|---|---|---|---|---|---|
| Accuracy | 0.82 | 0.91 | 0.84 | 0.86 | 0.88 | 0.79 | 0.87 |

The mathematical methods and numerical ML models explored a supervised classification of the compositional data of oil samples from spills that correspond to the experts' view from traditional oil geochemical analysis techniques (geographical location, stratigraphic level, diverse geochemical compositions, pressures, oil-water contacts and other geological indicators) and use of basic statistical classification tools (e.g., Multivariate Statistics).

In a systemic view of the set of compositional data available, the supervised classification uses the expert's understanding and experience regarding the possible differences between the various compositions, considering the universe of reservoirs and fluids sampled. According to information from collaborators, the geochemical compositions of the oils studied herein are recognized as being quite similar, reflecting geological circumstances that are unfavorable to the differentiation of the composition of the fluids (e.g., biodegradation, recharge, multiple reservoirs, diversity of generating sources and migration routes).

The deposits in the Basin to which the oils belong are characterized by large, fully connected reservoirs, thick oil columns and simple migration and filling schemes of the accumulations. Such characteristics are distinct from another neighboring Basin, in which specific geological factors and circumstances imposed a great diversity of geochemical compositions among the accumulated oils, favoring the establishment of distinctive compositional criteria and simpler statistical routines in the routine task of identifying spilled oily residues.

### 5. Application and Validation of the Model

After establishing the classification models of the compositions, with RF being chosen for its best accuracy, oils that were not part of the initial database had their origin diagnoses tested and the results evaluated according to their geological significance.

Three oil samples, A, B and C, from spills were used, with the same 62 attributes selected in the modeling, normalized according to the NSCORE function (Table 5 and FIG. 9).

TABLE 5
Prediction probabilities of the presented “case study”.

| Sample | Prediction | Probability |
|---|---|---|
| A | C051 | [′C051′, 0.55], [′C008′, 0.24], |
| | | [′C050′, 0.07], [′C006′, 0.03], |
| | | [′C001′, 0.03], [′C041′, 0.02], |
| | | [′C046′, 0.01], [′C045′, 0.01], |
| | | [′C034′, 0.01], [′C020′, 0.01], |
| | | [′C005′, 0.01], [′C004′, 0.01] |
| B | C045 | [′C045′, 0.86], [′C042′, 0.05], |
| | | [′C050′, 0.04], [′C051′, 0.01], |
| | | [′C048′, 0.01], [′C041′, 0.01], |
| | | [′C027′, 0.01], [′C001′, 0.01] |
| C | C045 | [′C045′, 0.91], [′C050′, 0.05], |
| | | [′C051′, 0.01], [′C041′, 0.01], |
| | | [′C027′, 0.01], [′C023′, 0.01] |

The probabilities of the numerical predictions correspond to the geological circumstances and location of the samples. Sample A, known to be a natural exudation, had its diagnosis justified (47% for C051 field and 26% for C008 field) according to its geochemical composition. Samples B and C correspond to accumulations adjacent to the C045 field, with predictions of 94% and 820 probability of belonging to C045, respectively, therefore adjusted to the geological situation.

### 6. Exploratory Feedback

Exploratory Feedback is new information or confirmation (via AI) of information already recognized or inferred, which is applicable to oil exploratory analysis. The application of ML algorithms to the analysis of the database of geochemical compositions of oils favors a “dialogue” between the numerical solutions and the traditional criteria based on the experience of the expert and less sophisticated statistical approaches. Such an approach allows a counterpart to the supervised classification, such as the categorization of the importance of attributes, listings of source predictions and respective probabilities.

The experience of the expert is what ends up producing the supervised classification of oil compositional data, which constitutes the first step towards the construction of a numerical classification model.

This sharing of information between mathematical methods and the expert's experience contributes to the deepening of the compositional analysis and greater geological understanding of the set of compositions and their distinctions, in other words, an exploratory feedback.

Some observations and additions to the established interpretations can be listed after the application tests:
a) There were 100% correct predictions of the origin of samples from fields/exploration areas C004, C005, C006, C007, C022, C011, C014, C015, C017, C018, C020, C021, C023, C026, C027, C028, C031, C032, C033, C034, C036, C037, C039, C040, C041, C043, C045, C046, C047, C048, C049, and C052;
b) There were 100% correct predictions of the origin of oils from the production fields (C048, C004, C050, C040, C041, C014, C049, C045, C006, C011);
c) Unlike the accumulations of C005 and C007, which presented 100% of hits, the 10% of erroneous predictions correspond largely to samples of C008 (although with 78% of hits), which were predicted by the model as belonging to C051. This result, although recorded as an “error”, is geologically quite understandable, since C008 is an accumulation resulting from the overflow of C051;
d) The fields that are most difficult to distinguish (C001 and C050) had an excellent level of prediction: C001 (99%) and C050 (96%);
e) C051 (552 samples) had 99.2% of correct predictions.

### 7. Conclusions

Finally, it is concluded that, with the aim of identifying the oil complex from spill samples, 2,200 samples and 75 attributes were used, which, after data processing and exploratory analysis using statistical methods, resulted in a total of 2,137 samples and 62 attributes.

Regarding the Machine Learning classification, with the database available, one predictive model stood out: Random Forest, with an overall accuracy of 91.0%. The application in 3 new spill samples was extremely important to continue guiding the activities currently being developed.

The results of the study allow validating the interpretative geochemical model assembled for these accumulations and the “supervised classification of experts” made available for the numerical test.

The mathematical routines and classification models allowed for greater reliability—given the use of artificial intelligence, which reduces the subjectivity of the human resources to obtain results—and speed—activities that used to take hours and/or days can be performed in minutes—in the diagnosis of the origin of oils from important production areas on the Brazilian coast.

Those skilled in the art will value the knowledge presented herein and will be able to reproduce the disclosure in the embodiments presented and in other variants, encompassed by the scope of the attached claims.

1. A method for crating a model for recognition of the origin of oil spills at sea by use of machine learning, the method comprising the following steps:
1) data entry and processing: the imported data set, containing predictive (independent) attributes in relation to the dependent variable (field) for the construction of the model, is evaluated, validated and organized;
2) exploratory analysis and attribute selection: univariate and multivariate methods are used to understand the statistical properties of the data and select a subset of attributes by using a distance matrix;
3) application of the machine learning: use of machine learning algorithms to generate models for recognizing the origin of oil spills at sea; for each algorithm, a model is proposed, along with its respective optimized parameters and attributes;
4) application and validation: selection of the classification model with the best adherence to the data set in order to be tested on new samples to predict the origin of the spill.

2. The method according to claim 1, wherein in step 1, experimental data derived from oil samples from regions of interest are imported, with pre-processing of the following parameters:
a) missing values: removal or replacement of the data;
b) inconsistent data: elimination of the values;
c) outliers: use of the isolation forest that removes these variables to clean the database.

3. Then method according to claim 1, wherein in step 1, the data is normalized.

4. The method according to claim 1, wherein in step 2, the Exploratory Data Analysis occurs through the use of histogram, correlation matrix, multidimensional scaling, linear discriminant analysis, principal component analyses and K-Means clustering.

5. Then method according to claim 1, in step 3, at least the following machine learning algorithms are used: Support Vector Machines (SVM), Gaussian Naive-Bayes (GNB), Artificial Neural Networks (ANN), Linear Discriminant Analysis (LDA), K-Nearest Neighbors (KNN), Random Forest (RF), Decision Trees (DT).
